(19) United States
(12) Patent Application Publication
(10) Pub. No.: US 2013/0171428 A1
(43) Pub. Date: Jul. 4, 2013

(54) SYSTEMS AND METHODS FOR FORMING AN IMAGE ON A DEVICE

(71) Applicant: Russell Brian Taylor, Ladera Ranch, CA (US)

(72) Inventor: Russell Brian Taylor, Ladera Ranch, CA (US)

(21) Appl. No.: 13/341,236

(22) Filed: Dec. 30, 2011

(51) Int. Cl. B32B 3/00; C08J 7/04; C03C 25/00; B05C 11/00; C23C 14/30; B29C 35/08

(52) U.S. Cl. 428/195.1; 427/596; 264/400; 216/39; 118/697; 427/511

(57) ABSTRACT

An image can be formed onto a device such as a cell phone or a tablet by laser engraving the image onto a housing of the device. A coloring agent can then be applied to the engraved image to modify the color of the image. The coloring agent can darken the engraved image. The coloring agent can include multiple colors of ink (e.g., UV curing ink) that can be applied to form a multi-color image. The coloring agent can be applied without requiring the use of a masking layer, for example, by aligning the laser engraved image with a coloring agent applicator so that the coloring agent is applied to substantially only the engraved image on the device.

### BACKGROUND

1. Field of the Disclosure

Some embodiments of this disclosure relate to the formation of images onto devices such as electronic devices (e.g., cell phones and tablets).

2. Description of the Related Art

It can be desirable to form an image on a device such as a cell phone or a tablet. For example, users of electronic devices may desire to personalize their devices with pictorial images, logos, phrases of text, or other images, or a company may desire to form a logo or other identifying information on electronic devices issued to its employees. Although various methods of forming images onto devices are known, these methods suffer from various drawbacks. For example, some image formation techniques (e.g., stickers and other additive techniques) result in a non-permanent image that can wear off or be removed. Some image forming techniques involve forming the image onto an after-market case or onto a removable portion of the device, also allowing the image to be removed. Some image forming techniques are compatible with only certain materials (e.g., plastic) and are not compatible with other materials (e.g., metal). Some image forming techniques do not form a color image, or form only a single-color image, thus limiting the types of images that can be formed. Some of the embodiments disclosed herein overcome one or more of these disadvantages.

### SUMMARY OF CERTAIN EMBODIMENTS

Some embodiments of the disclosure relate to a method for forming a multi-color image on a device. The method can include engraving an image onto a device, and applying ink of multiple colors to the image. A first portion of the image can have a first color and a second portion of the image can have a second color.

Engraving the image can be performed using a laser engraving system. Engraving the image can include positioning the device relative to a laser of a laser engraving system, accessing image data, accessing orientation data associated with the device, and operating the laser based on the image data and the orientation data to engrave the image onto the device.

Applying the ink can include positioning the device relative to an applicator of a printing system, accessing the image data, accessing the orientation data associated with the device, and operating the applicator based on the image data and the orientation data to apply the ink to the image. The ink can be applied to substantially only a region intended for the engraved image on the device, and the remaining portions of the device can be substantially or entirely free from applied ink. The ink can include a UV curing ink, and the method can further include applying UV light to cure the ink.

In some embodiments, the method can further include applying a base ink to the image before applying the ink of multiple colors to the image. In some embodiments, the method can further include applying a UV primer to the image before applying the ink. In some embodiments, the method can further include applying the UV primer to the image after applying the ink. In some embodiments, the method further includes applying a top coat to the image after applying the ink.

The image can include text. The image can include a pictorial image. The device can be an electronic device. The device can include a metal surface and the image can be engraved onto the metal surface.

Some embodiments disclosed herein relate to systems for forming a multi-color image on a device. The system can include a laser engraving system that can have a laser configured to engrave an image onto a device, and a printing system that can have an applicator configured to apply ink of multiple colors to the image such that a first portion of the image has a first color and a second portion of the image has a second color.

The system can further include a controller, which can have a computer processor, and a computer-readable medium comprising image data, orientation data associated with the device, and computer executable instructions configured to be executed by the computer processor to operate the laser based on the image data and the orientation data to engrave the image onto the device, and operate the applicator based on the image data and the orientation data to apply the ink to the image. The controller can be configured to apply the ink to substantially only the engraved image on the device.

Some embodiments disclosed herein relate to a device having a multi-color image formed thereon. The device can include a housing having an image engraved thereon, and ink of multiple colors on the image. A first portion of the image can have a first color and a second portion of the image can have a second color.

The ink can include a UV curing ink. The device can include a base ink under the ink of multiple colors.

The image can include text. The image can include a pictorial image.

The device can be an electronic device. The device can include a metal surface and the image can be engraved onto the metal surface.

Some embodiments disclosed herein relate to a method of forming an image onto an electronic device. The method can include engraving an image onto an electronic device, and applying a coloring agent to the image to modify the color of the image without requiring the use of a removable masking layer. In some embodiments, the coloring agent can be applied using a printing system configured to precisely apply the coloring agent with sufficient resolution to create a detailed (e.g., pictorial) image.

Engraving the image can include positioning the electronic device relative to a laser of a laser engraving system, accessing image data, accessing orientation data associated with the electronic device, and operating the laser based on the image data and the orientation data to engrave the image onto the electronic device.

Applying the ink can include positioning the device relative to an applicator of a printing system, accessing the image data, accessing the orientation data associated with the device, and operating the applicator based on the image data and the orientation data to apply the ink to the image. The ink can be applied to substantially only the engraved image on the device, and the remaining portions of the device can be substantially or entirely free from applied ink.

The coloring agent can include a darkening agent configured to darken the engraved image. The coloring agent can include an oxidizing agent. The coloring agent can include UV curing ink. The method can include applying a base ink to the image before applying the UV curing ink. The method can include applying the UV primer to the image after applying the UV curing ink. The method can include applying a top coat to the image after applying the coloring agent.

The electronic device can include a metal surface and wherein the image is engraved onto the metal surface.

Some embodiments disclosed herein relate to a method of forming an image onto a device. The method can include engraving an image onto an electronic device. The electronic device can have a base material and a coating material above the base material. Engraving the image can include removing the coating material to expose the base material for an image area. The method can include applying a coloring agent to the image area, and the coloring agent can be configured to cause a chemical reaction with the base material to change the color of the image.

The coloring agent can be a darkening agent configured to darken the image. The base material can be a metal, such as, for example, aluminum. The device can be an electronic device. The coloring agent can include an acidic liquid. The chemical reaction can form a layer of an oxide of the base material in the image area.

Some embodiments disclosed herein relate to a device having an image formed thereon. The device can include a housing having a base material and a coating material above the base material, and an image engraved onto the housing. The image can have an image area with the coating material removed to expose the base material. The device can have a layer of material in the image area, and the material can include an oxide of the base material. The oxide of the base material can have a different color than the base material.

The base material can be a metal, such as, for example, aluminum. The device can be an electronic device.

### BRIEF DESCRIPTION OF THE DRAWINGS

Certain embodiments will now be discussed in detail with reference to the following figures. These figures are provided for illustrative purposes only, and the embodiments are not limited to the subject matter illustrated in the figures.

FIG. 1 is a schematic view of an example embodiment of a system for forming an image on a device.

FIG. 2 is an example embodiment of a method for engraving an image on the device.

FIG. 3 is an example embodiment of a method for printing an image onto the engraved portion of the device.

FIG. 4 is an example embodiment of a method for modifying the color of the engraved image.

FIG. 5 is an example embodiment of an electronic display device.

FIG. 6 is a back view of the electronic device of FIG. 5.

FIG. 7 is a cross-sectional view taken across the line 7-7 of FIG. 6.

### DETAILED DESCRIPTION OF CERTAIN EMBODIMENTS

The following detailed description is now directed to certain specific example embodiments of the disclosure. In this description, reference is made to the drawings wherein like parts are designated with like numerals throughout the description and the drawings.

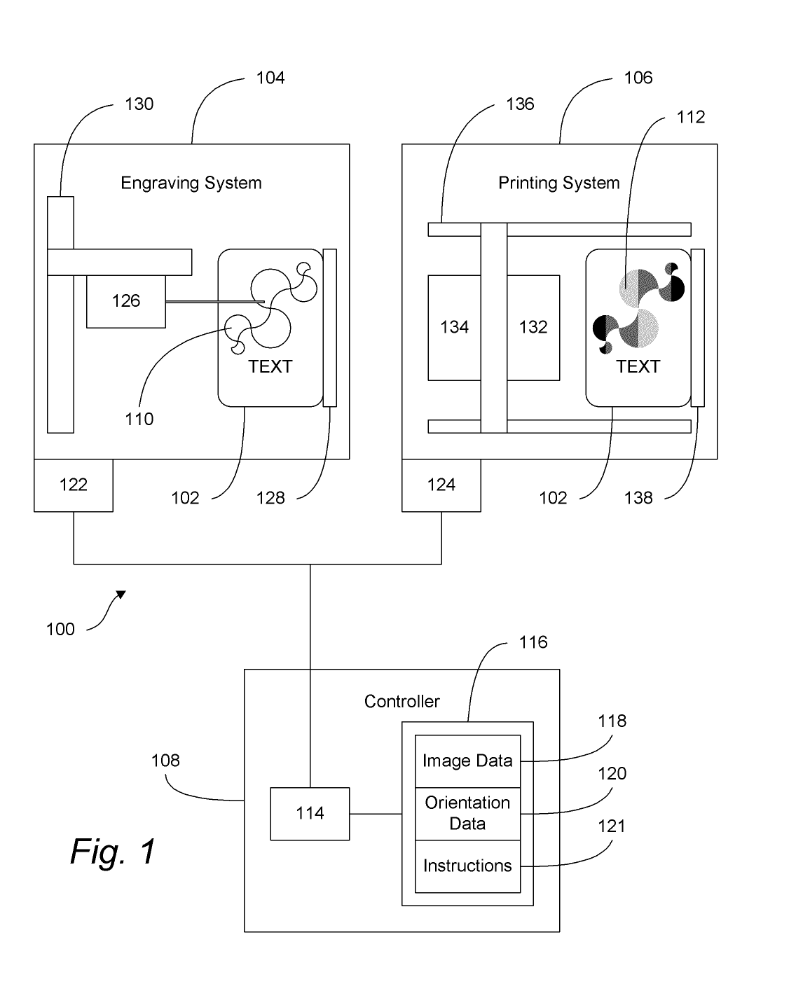

FIG. 1 schematically shows an example embodiment of a system 100 for forming an image onto a device 102. The systems and method described herein can be used to form an image onto various types of devices, including electronic devices such as cell phones, tablets, and laptop computers. Other devices can also be used such as watches, jewelry, machinery, furniture, etc. The system 100 can include an engraving system 104 and a printing system 106. As described herein, the engraving system 104 can be used to form an engraved image 110 on the device 102, and the printing system 106 can be used to apply a coloring agent to the engraved image 110, thereby forming the image 112.

A controller 108 can be used to control the engraving system 104 and/or the printing system 106. The controller 108 can include a computer processor 114 that is in communication with computer-readable memory 116. The computer processor 114 can be a general purpose processor, or a specialized processor or integrated circuit configured specifically designed for operation of the engraving system 104 and/or the printing system 106. In some embodiments, the computer processor 114 can include multiple processors in a single computing device or distributed across multiple computing devices (e.g., over a network). The computer-readable memory 116 can be, for example, a non-transitory computer-readable medium such as a hard drive disc, RAM, or any suitable volatile or non-volatile memory module.

The computer-readable memory 116 can include image data 118, which can be an electronic representation of the image to be formed onto the device. In some embodiments, the image data 118 can include multiple components. For example, the image data 118 can include coverage area data, similar to a silhouette of the image, for use by the engraving system 104. The image data 118 can include color data representative of what colors are to be applied to various portions of the image 112. The image data 118 can also include base coat information representative of a primer or base coat for application before the image 112. The image data 118 can be, at least in part, user-selectable. For example, an owner of the device 102 can select or submit an image to be formed onto the device 102. The controller 108 can receive user selection or submissions via a network or the internet. In some embodiments the selected or submitted image can be used as the image data 118, or the image data 118 can be generated from the selected or submitted image. For example, the resolution of the image may be resized, a color scheme may be adjusted (e.g., converted from RGB to CMYK), and coverage area and/or base coat information may be extracted from a multi-color image.

The computer-readable memory 116 can also include orientation data 120. The orientation data can include information representative of the location on the device 102 for the image. In some embodiments, at least a portion of the orientation data 120 can be specified by the user for the particular image being formed. The orientation data 120 can include dimensions for the device 102 receiving the image. Thus, in some embodiments, at least a portion of the orientation data 120 is set by the type of device 102, not by the user. In some embodiments, the orientation data 120 can include an offset between a portion of the image (e.g., the center or corner of the image) and a portion of the device 102 (e.g., the center or corner of the device 102). If a user specifies that an image is to be positioned on a particular location on the device 102, the offset used to properly position the image can be larger for a device with larger dimensions and the offset can be smaller for a device with smaller dimensions. In some embodiments, the orientation data 120 can be incorporated into the same file as the image data 118. For example, an electronic image file can include a blank space area that defines the offset for the image and/or corresponds to dimensions of the device 102. In some embodiments, a graphical user interface can be used to position the image on the device 102. For example, a template for the type of device can be displayed on a graphical user interface, and the template can be representative of the dimensions of the device 102. An operator can position a representation of the image onto the graphical display of the template at a specified location. The orientation data 120 can be derived from the template information and/or the position of the representation of the image on the graphical display.

The computer-readable memory 116 can include computer-readable instructions 121 configured to be executed by the processor 114 to form an image onto a device 102 as described herein (e.g., by executing the methods described herein). The controller 108 can be in communication with the engraving system 104 and/or the printing system 106 by cables, or wireless communication links, or other suitable communication method. In some embodiments, the controller 108 can communicate with an engraving system controller 122, which can be configured to receive instructions and operate the engraving system to carry out the instructions to form the engraved image 110 on the device 102. The engraving system controller 122 can include a processor and computer-readable memory, in some cases. In some embodiments, the controller 108 can communicate with a printing system controller 124, which can be configured to receive instructions and operate the printing system to carry out the instructions to apply the coloring agent to form the image 112. The printing system controller 124 can include a processor and computer-readable memory, in some cases.

Although shown in FIG. 1 as separate components, two or more of the engraving system 104, printing system 106, and controller 108 can be incorporated into a single system. For example, the engraving system 104 and the printing system 106 can be incorporated into a single system that perform the engraving and also applies the coloring agent without the device 102 being transferred from one physical system to another. In some embodiments, the controller 108 can also be incorporated into the single system, or an external computing device can operate the single system.

In some embodiments, certain features of FIG. 1 can be omitted. For example, the controller 108 can operate the engraving system 104 and/or the printing system 106 directly so that the engraving system controller 122 and/or the printing system controller 124 can be omitted. In some embodiments, the shared controller 108 can be omitted, and the engraving system controller 122 and/or the printing system controller 124 can be used to control the engraving and/or the coloring agent application. Also, in some embodiments, the engraving system 104 can be omitted, and the system 100 can be configured to form the image 112 onto a device 102 that already has an engraved image 110 thereon. Also, in some embodiments, the printing system 106 can be omitted, and the system 100 can be configured to engrave the image 110 without applying a coloring agent.

With further reference to FIG. 1, the engraving system 104 can be a laser engraving system configured to use a laser 126 to engrave the image 110 onto the device 102. Various types of lasers can be used such as a CO₂ laser, a fiber laser, etc. The particular laser and setting used can vary depending on the material of the device 102. By way of example, for an electronic device having an aluminum housing, a CO₂ laser (such as those sold by Trotec Laser, Inc. of Ypsilanti, Mich.) can be used with a laser height set to at least about 0.25 inches and/or less than or equal to about 0.45 inches, or about 0.35 in inches above the surface of the device 102. The power of the laser can be set to a percentage of an output power (e.g., a maximum power such as about 30 watts), and the percentage can be at least about 70% and/or less than or equal to about 90%, or about 80%. The velocity of the movement of the laser 126 and/or the device 102 relative to the other can also be set as a percentage of a velocity (e.g., a maximum velocity such as about 140 inches per second), and the percentage can be at least about 60% and/or less than or equal to about 80%, or about 70%. Other values can be used (in some cases outside of these ranges) depending, for example, on the material of the device 102, the laser of the engraving system 104, and/or the image 110 being formed.

The engraving system 104 can include a holder configured to hold the device 102 during the engraving process. The holder can be a generally flat surface on which the device 102 can rest. In some embodiments, the engraving system 104 can include an orientation element 128 configured to position the device 102 at a location in the engraving system 104. The orientation element 128 can include one or more positioners, such as protrusions configured to position the device 102 at the location when the device 102 is rested against the one or more protrusions. The orientation element can include one or more indicators, such as markings configured to position the device 102 at the location when the device 102 is placed according to the one or more markings. Various other types of orienting elements can be used, such as one or more clamps, one or more notches, etc. In some embodiments, the orienting element 128 can be configured to secure the device 102 in place to prevent shifting of the device during the engraving process.

In some embodiments, the laser 126 can be mounted onto one or more actuators 130 (e.g., arms) that are configured to move the laser 126 during the laser engraving process, and the laser 126 and/or the device 102 can each be configured to move relative to the other. In some embodiments, the laser 126 can be movable along a plurality of dimensions, such as the X and Y axes (e.g., using two arms). In some embodiments, the laser 126 can be held stationary, while the device 102 is moved (e.g., along the X and Y axes) by the device holder of the engraving system. In some embodiments, the laser 126 and the device 102 can both be movable. For example, the laser 126 can be movable along a first axis (e.g., the X axis) and the engraving system can be configured to move the device 102 along a second, substantially orthogonal axis (e.g., the Y axis).

The engraving system controller 122 can be configured to receive instructions from the controller 108 and to operate the laser 126 move the laser 126 across the device 102 (e.g., using the arms 30) and activate the laser in response to the instructions, thereby forming the engraved image 110 onto the specified location on the device 102. The instructions received by the engraving system controller 122 can include the image data 118 and the orientation data 120.

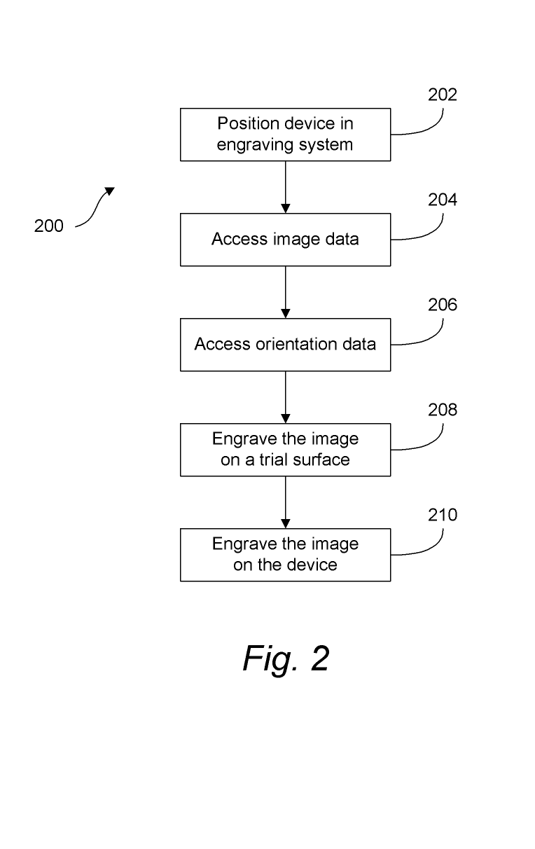

FIG. 2 shows an example embodiment of a method 200 for engraving the image 110 onto a device 102. The method 200 of FIG. 2 can be performed by the engraving system 104 of FIG. 1 or any other suitable engraving system. At block 202, the device 102 can be positioned in the engraving system 104. The orienting element 128 can be used to position the device 102 within the engraving system 104. At block 204, the engraving system 104 can access the image data 118, which can be received from the controller 108. The image data 118 used by the engraving system 104 can include a solid, silhouette (e.g., black) version of the image to be engraved onto the device 102. At block 206, the engraving system 104 can access the orientation data 120, which can be received from the controller 108. In some embodiments, the image data 118 and orientations data 120 can be received together (e.g., as a single file). At block 210, based on the image data 118 and the orientation data 120, the engraving system 104 can move the laser 126 across the device 102 and activate the laser 126 to engrave the image 110 onto the device 102. The laser 126 can vaporize, or otherwise modify, portions of the surface of the device 102 to form the image 110.

In some embodiments, an optional trial run can be performed at block 208 before the image 110 is engraved onto the device 102. The device 102 can be placed in the engraving system 104 with a trial surface positioned over the portion of the device 102 receiving the image 110. A blocking device, such as painter's tape, can be adhered to the surface of the device 102 for use as the trial surface, although various other types of trial surfaces can be used. In some embodiment, a layer can be deposited onto the tape (e.g., ink applied with a marker) so that the trial engraving will etch away the layer to reveal the image being engraved. At block 208, the laser 126 can be operated with trial settings, which can be reduced power settings configured to engrave an image into the trial surface without engraving the surface of the device 102. For example, at block 208, the CO₂ laser discussed above can be operated at a power percentage of at least about 10% and/or less than or equal to about 30%, or about 20%, although other settings can be used depending on the material of the device 102, the laser 126, and the image being formed. In some embodiments, the same height and velocity settings can be used for the trail engraving and the final engraving, although these settings can also be changed to reduce the material removed during the trial engraving (e.g., by increasing the velocity).

In some embodiments, the operator can view the image formed onto the trial surface to confirm the features (e.g., size, orientation, location) of the image. Once approved, the method 200 can proceed to block 210, in which the laser 126 is operated at settings configured to engrave the image 110 onto the surface of the device 102. In some embodiments, the trial surface can be removed from the device 102 after the image is engraved onto the trial surface but before engraving onto the device 102. In some cases, the device 102 can be removed from the engraving system for removal of the trial surface or for inspection of the image engraved onto the trial surface. Thus, in some cases, the device 102 can be repositioned into the engraving system 104 before the image is engraved onto the device at block 210. In some embodiments, the device 102 can be left in the engraving system 104 (which can have an observation window that allows viewing of the device 102 after the image is engraved) after the engraving of the trial surface at block 208, thereby preventing misplacement of the device. In some embodiments, the trial surface can remain on the device during block 210 and the laser 126 can remove the remaining image portions of the trial surface as the laser 126 engraves the image 110 onto the device 102.

With further reference to FIG. 1, the printing system 106 can include an applicator 132 for applying a coloring agent to the device 102. The coloring agent can be used to modify the coloring of the engraved image, such as by changing a color or grey-scale darkness of the engraved image. In some embodiments, the coloring agent can be ink, such as UV curing ink, and the printing system 106 can include a UV light source 134 for curing the ink. The printing system 106 can be configured to combine multiple colors of ink to produce different colors at different portions of the image. For example, the printing system 106 can use cyan, magenta, yellow, and black (CMYK) ink to form a wide variety of colors, although other color schemes can also be used (e.g., red, blue, green (RGB)). The printing system 106 can be configured to apply the coloring agent (e.g., ink) with a high enough resolution so that the different colors applied to different portions of the image can be merged by a human eye to produce a high-quality, multi-color image. The printing system 106 can apply the coloring agent (e.g., ink) with a resolution of at least about 180 dots per inch (DPI), at least about 360 DPI, at least about 720 DPI, or at least about 1440 DPI, although other resolutions can also be used. Thus, the coloring agent can be applied with sufficient resolution to form a detailed (e.g., pictorial) image, instead of being applied by an imprecise application technique (e.g., spray, brush, or wipe). Use of an imprecise application technique can result in waste of the coloring agent by over application outside the engraved image area, can result in added complication to the process by requiring the use of removable masking layer, and can lack sufficient precision to create detailed multi-color images. The printing system 106 can be configured to apply the coloring agent (e.g., ink) to substantially only the engraved area 110 of the device 102, with substantially no coloring agent applied to non-engraved portions of the device 102. Thus, the coloring agent can be applied to the device 102 without requiring the use of a masking layer to prevent the ink from contacting the non-engraved portions of the device. Various printers can be used, such as a UJF printer from Mimaki Engineering Co., Ltd. of Suwanee, Ga., or a Direct Jet UV printer from Direct Color Systems of Rocky Hill, Conn.

One or more actuators 136 can be used to move the applicator 132 across the device so that the coloring agent can be applied to the specified portions of the device 102 to form the image 112. In some embodiments, the applicator 132 can move along one axis while the printing system 106 moves the device 102 along a second, substantially orthogonal axis. In some embodiments, the applicator 132 can remain stationary while the printing system 106 moves the device 102.

The printing system 106 can include a holder configured to hold the device 102 during the printing process. The holder can be a generally flat surface on which the device 102 can rest. In some embodiments, the printing system 106 can include an orientation element 138 configured to position the device 102 at a location in the printing system 106. The orientation element 138 can include one or more positioners, such as protrusions configured to position the device 102 at the location when the device 102 is rested against the one or more protrusions. The orientation element 138 can include one or more indicators, such as markings configured to position the device 102 at the location when the device 102 is placed according to the one or more markings. Various other types of orienting elements can be used, such as one or more clamps, one or more notches, etc. In some embodiments, the orienting element 138 can be configured to secure the device 102 in place to prevent shifting of the device during the printing process.

The printing system controller 124 can be configured to receive instructions from the controller 108 and to operate the applicator 132 laser in response to the instructions, thereby applying the coloring agent onto the specified location on the device 102 to form the image 112. The instructions received by the engraving system controller 122 can include the image data 118 and the orientation data 120.

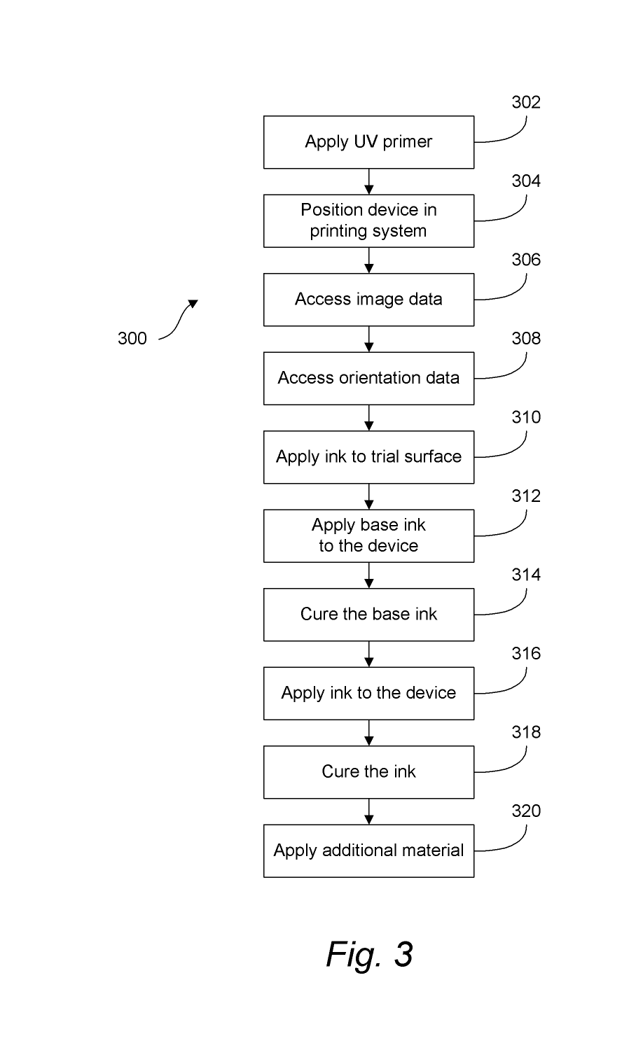

FIG. 3 shows an example embodiment of a method 300 for applying the coloring agent to the device 102. The method 300 of FIG. 3 can be performed using the printing system 106 of FIG. 1, or any other suitable system. At block 302, a primer material, such as a UV primer, can be applied to the engraved portion of the device 102. A UV primer can improve the adhesion of UV curable ink to the underlying material of the device 102. One example UV primer that can be used is GlassBoost, available from National UV Supply Company, Inc. of Apopka, Fla. Various other primer materials can be used to increase the adhesion or effectiveness of the coloring agent. In some embodiments the primer of block 302 can be omitted.

At block 304, the device 102 can be positioned in the printing system 106. In some embodiments in which a single system can be used for engraving and printing, block 304 can be omitted and the device 102 can remain as positioned during the engraving process. In some embodiments, the orienting element 138 can be used to position the device 102 at a specified location so that the coloring agent can be applied onto the specified portion of the device 102.

At block 306, the printing system 106 can access the image data 118, which can be received from the controller 108. The image data 118 used by the printing system 106 can include color printing information (e.g., in CMYK format) indicating different colors to be applied to different portions of the image. In some embodiments, the image data 118 used by the printing system 106 can include a solid, silhouette version of the image for use in applying a base coat below the multi-color ink. At block 308, the printing system 106 can access the orientation data 120, which can be received from the controller 108. In some embodiments, the image data 118 and orientations data 120 can be received together (e.g., as a single file). In some embodiments, the same image data 118 and/or the same orientation data 120 can be used in the engraving process and the printing process. In some embodiments, if a single system is used for both the engraving and printing, blocks 306 and/or 308 can be omitted in some cases and the same image data 118 and/or orientation data 120 can be used for both the engraving and printing.

At block 316, the printing system 106 can operate the applicator 132 based on the image data 118 and the orientation data 120, to move the applicator 132 and or the device 102 with respect to each other and to apply the coloring agent to the device 102. In some embodiments, multiple colors of ink can be used, and different combinations of colors can be applied to different portions of the image to produce a multi-color image 112 on the device. By using the image data 118 and orientation data 120, the printing system 106 can apply the coloring agent to substantially only the engraved portions of the device 102. Because the coloring agent can be applied with substantially no overfilling outside of the engraved area, the coloring agent can be applied without requiring the use of a masking layer. Because the applicator 132 can apply different combinations of colors to different portions of the image, multiple colors can be applied in a single pass of the applicator 132. The applicator can be configured to precisely apply the coloring agent to create a detailed (e.g., multi-color) image as discussed above.

If a UV curing ink is used, at block 318, UV light can be applied to the device by the UV light source 134 to cure the ink. If other types of ink are used (e.g., thermal curing ink), other curing processes can be used (e.g., heat).

In some embodiments, a base ink can optionally be applied at block 312. The base ink can be applied before the main ink used for forming the image 112, and the base ink can be a single solid color to create an even base color on which the main colored ink can be applied at block 316. In some embodiments, the main colored ink that is applied at block 316 can be a subtractive color scheme (e.g., CMYK), and the base ink applied at block 312 can form a light colored (e.g., white) background for the colored ink applied at block 316. The base ink can be applied using the applicator 132 in a manner similar to that discussed in connection with block 316. The base ink can be applied substantially only to the engraved portions of the device 102 by operating the applicator 132 based on the image data 118 and the orientation data 120. If a UV curing base ink is applied at block 312, UV light from the UV light source 134 can be used to cure the base ink at block 314.

In some embodiments, a printing test run can be performed at block 310 by applying ink to a trial surface. A clear tape can be used as the trial surface, and can be adhered onto the device 102 over the engraved portion of the device 102. A trial version of the image can be applied to the trial surface to confirm that the image will be aligned with the engraved portion of the device 102. The trial version of the image can be the same as the base image (to be applied at block 312), or the same as the main image (to be applied at block 316), or the trial image can be a reduced-ink version of the image having the same shape as the main image so that the alignment can be checked while using less ink. The trial image can be applied to the trial surface by the applicator 132 in the same manner as discussed in connection with blocks 312 and 316 using the image data 118 and the orientation data 120. In some embodiments, the operator can view the trial image formed onto the trial surface to confirm that the image is aligned with the engraved portion of the device 102. If needed, the device 102 position can be adjusted and block 310 can be repeated until the device position in the printing system 106 causes the trial image to align with the engraved portion of the device 102. Once approved, the trial surface can be removed from the device 102 and the method 300 can proceed to apply the image to the device 102.

In some embodiments, one or more additional materials can optionally be applied over the ink at block 320. In some embodiments, a UV primer material (e.g., GlassBoost) can be applied after the ink to reinforce the adhesion of the ink and/or to act as a clear coat over the ink. In some embodiments, a covering (e.g., a plastic laminate) can be applied over the image to protect the image. In some embodiments, the adhesion of the ink to the device 102 is sufficient that no covering layer is used over the image.

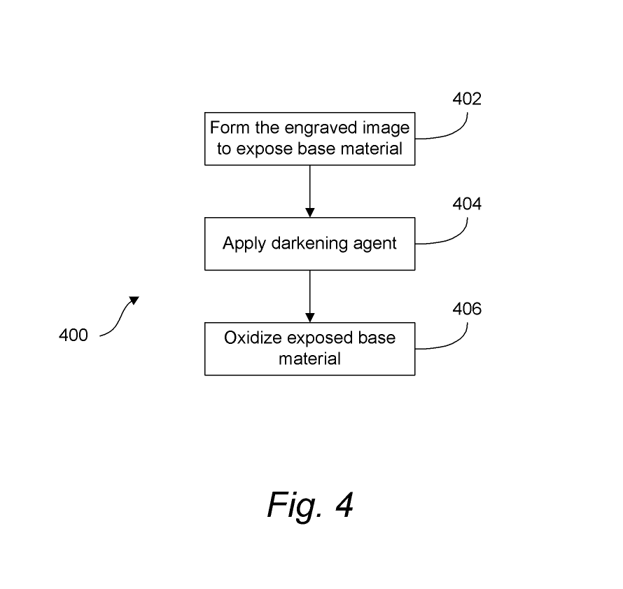

FIG. 4 shows an example method 400 for applying a coloring agent configured to darken the engraved image 110. At block 402, an image can be engraved onto the device 102 in a manner similar to the method 200 of FIG. 2. In some embodiments, a fiber laser (such as those sold by Trotec Laser, Inc. of Ypsilanti, Mich.) can be used to form the engraved image. The height of the laser can be set to at least about 2 inches and/or less than or equal to 2.5 inches, or about 2.19 inches over the surface of the device 102. The power of the laser can be set to a percentage of an output power (e.g., a maximum power such as about 30 watts), and the percentage can be at least about 70%, at least about 80%, or 100%. The velocity of the movement of the laser 126 and/or the device 102 relative to the other can also be set as a percentage of a velocity (e.g., a maximum velocity such as about 140 inches per second), and the percentage can be at least about 15% and/or less than or equal to about 35%, or about 25%. Other values can be used (in some cases outside of these ranges) depending, for example, on the material of the device 102, the laser of the engraving system 104, and/or the image 110 being formed. The device 102 can have a base material that can oxidize (e.g., a metal such as aluminum) with a coating applied over the top thereof. The coating can protect the underlying base material and/or provide other benefits such as improved gripping or coloring. The coating can provide resistance in the underlying base material against oxidizing. The engraving process of block 402 can remove the coating for the area of the image, thereby exposing the underlying base material. In some cases, the engraving of block 402 can also remove a portion of the base material for the area of the image.

In some embodiments, a trail engraving operation can be performed before the image is permanently engraved onto the device 102, in a manner similar to that discussed in block 208 of FIG. 2. A trial surface, such as a blocking device (e.g., painters tape) can be applied to the surface of the device 102, and the laser 126 can be operated at altered settings to reduce the amount of material removed during the trial engraving operation. The power can be set to at least about 10% and/or less than or equal to about 30%, or about 20%. The velocity can be set to about 60% and/or less than or equal to about 80%, or about 70%. Other settings can be used depending on the material of the trial surface, the laser 126, and/or the image being engraved.

At block 404, a coloring agent can be applied to the engraved image. The coloring agent can be a darkening agent, such as a chemical configured to cause oxidation of the base material (e.g., an oxidizing agent). For example, if an aluminum base material is used, the darkening agent can be an Aluminum Black chemical sold by Birchwood Casey, Inc. of Eden Prairie, Minn. In some embodiments, other acidic chemicals can be used to induce oxidation of the base material (e.g., aluminum). The coloring agent can be applied by an applicator similar to the applicator 132 of the printing system 106 of FIG. 1. For example, the applicator can apply the coloring agent to substantially only the engraved portion of the device 102 by using the image data 118 and the orientation data 120 as discussed above. In some embodiments, the coloring agent can be applied manually. For example, an operator can apply the coloring agent with a cloth so that the coloring agent contacts both the engraved area and the non-engraved surrounding area. The coating can prevent the coloring agent from oxidizing or otherwise affecting the base material for the non-engraved area. But for the engraved area, the coloring agent can contact the base material and modify the color thereof. For example, at block 406, the coloring agent can oxidize the exposed base material for the engraved area. As the base material oxidizes, it can change in color, such as by darkening. In some embodiments, the base material can darken to a deep black color. Other coloring agents can be applied to modify the coloring of the engraved image in different ways.

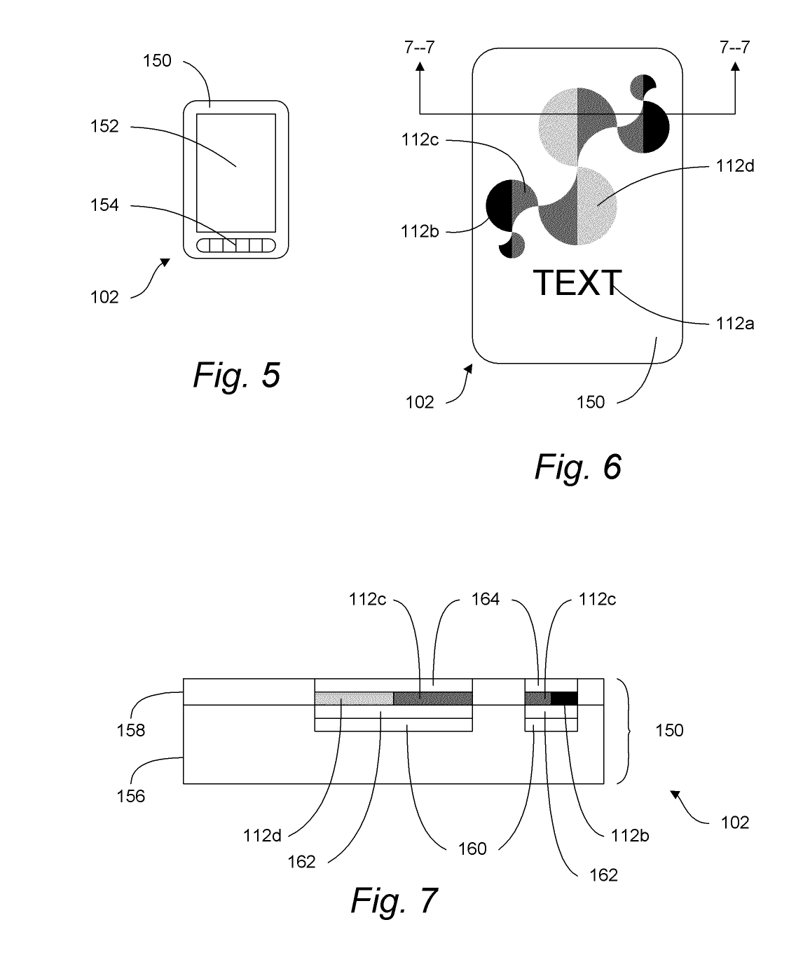

FIG. 5 shows an example embodiment of an electronic device 102 having a housing 150, a screen 152, and controls 154. FIG. 6 shows an enlarged view of the back of the device 102 having an image 112 formed on the housing 150. The image 112 can be formed on other suitable portions of the device 102 as well. The image 112 can include a text portion 112a, in some embodiments. The image 112 can include pictorial elements as well having multiple colors. In the illustrated embodiment, a first color portion 112b can be adjacent to a second color portion 112c, and the second color portion 112c can be adjacent to a third color portion 112d. In some embodiments, many more colors can be used than those shown in FIG. 6.

FIG. 7 is a cross-sectional view of the electronic device 102 taken across the line 7-7 of FIG. 6. The housing 150 can include a base material 156 and a coating 158, as discussed above. The engraving process can remove the coating 158 from the area of the image to expose the base material 156 and a portion of the base material 156 is also removed from the image area. In some embodiments, the device 102 can include a primer material 160 applied to the base material 156. A base color layer 162 can be located below the image 112 to provide a base color for the image 112. As mentioned above the image 112 can include different colors at different portions of the image 112. For example, a first color portion 112b of the image 112 can be adjacent to a second color portion 112c, and the second color portion 112c can be adjacent to a third color portion 112d. Because the image 112 can be applied with precision using the image data 118 and orientation data 120, the different colors can be applied to form detailed multi-color images without requiring the use of a masking layer. In some embodiments, additional material 164 can be above the image 112. For example, a UV primer can be applied above the image 112 and/or a protective coating can be applied over the image 112.

Some of the layers shown in FIG. 7 can be omitted. For example, in some embodiments, no primer layer 160 is used. In some embodiments, no base ink layer 162 is used. In some embodiments, the image 112 can be a single color. In some embodiments, no additional materials 164 are applied above the image 112. In some embodiments, the image 112 is formed as an oxidized layer of the base material 156 (e.g., as discussed in connection with FIG. 4).

The methods disclosed herein for forming an image on a device 102 can be performed directly onto the device 102 without dissembling the device 102. In some embodiments, the image 112 can be formed directly onto the original housing of the device 102, not to a supplemental case or replacement cover (although the methods and systems disclosed herein can also be used for forming images onto supplemental cases, replacement coverings, or other after-market products.

Embodiments have been described in connection with the accompanying drawings. However, it should be understood that the foregoing embodiments have been described at a level of detail to allow one of ordinary skill in the art to make and use the devices, systems, and methods described herein. A wide variety of variation is possible. Components, elements, and/or steps may be altered, added, removed, or rearranged. Additionally, processing steps may be added, removed, or reordered. While certain embodiments have been explicitly described, other embodiments will also be apparent to those of ordinary skill in the art based on this disclosure.

Some aspects of the systems and methods described herein can advantageously be implemented using, for example, computer software, hardware, firmware, or any combination of software, hardware, and firmware. Software can comprise computer executable code for performing the functions described herein. In some embodiments, computer-executable code is executed by one or more general purpose computers. However, a skilled artisan will appreciate, in light of this disclosure, that any module that can be implemented using software to be executed on a general purpose computer can also be implemented using a different combination of hardware, software, or firmware. For example, such a module can be implemented completely in hardware using a combination of integrated circuits. Alternatively or additionally, such a module can be implemented completely or partially using specialized computers designed to perform the particular functions described herein rather than by general purpose computers.

While certain embodiments have been explicitly described, other embodiments will become apparent to those of ordinary skill in the art based on this disclosure. Therefore, the scope of the invention is intended to be defined by reference to the claims as ultimately published in one or more publications or issued in one or more patents and not simply with regard to the explicitly described embodiments.

What is claimed is:

1. A method for forming a multi-color image on a device, the method comprising:
engraving an image onto a device; and
applying ink of multiple colors to the image, a first portion of the image having a first color and a second portion of the image having a second color.

2. The method of claim 1, wherein engraving the image is performed using a laser engraving system.

3. The method of claim 1, wherein engraving the image comprises:
positioning the device relative to a laser of a laser engraving system;
accessing image data;
accessing orientation data associated with the device; and
operating the laser based on the image data and the orientation data to engrave the image onto the device.

4. The method of claim 3, wherein applying the ink comprises:
positioning the device relative to an applicator of a printing system;
accessing the image data;
accessing the orientation data associated with the device; and
operating the applicator based on the image data and the orientation data to apply the ink to the image.

5. The method of claim 4, wherein that the ink is applied to substantially only the engraved image on the device.

6. The method of claim 1, wherein the ink comprises a UV curing ink, the method further comprising applying UV light to cure the ink.

7. The method of claim 1, further comprising applying a base ink to the image before applying the ink of multiple colors to the image.

8. The method of claim 1, further comprising applying a UV primer to the image before applying the ink.

9. The method of claim 8, further comprising applying the UV primer to the image after applying the ink.

10. The method of claim 1, further comprising applying a top coat to the image after applying the ink.

11. The method of claim 1, wherein the device comprises a metal surface and wherein the image is engraved onto the metal surface.

12. A system for forming a multi-color image on a device, the system comprising:
a laser engraving system comprising a laser configured to engrave an image onto a device; and
a printing system comprising an applicator configured to apply ink of multiple colors to the image such that a first portion of the image has a first color and a second portion of the image has a second color.

13. The system of claim 12, further comprising a controller comprising:
a computer processor; and
a computer-readable medium comprising image data, orientation data associated with the device, and computer executable instructions configured to be executed by the computer processor to:
operate the laser based on the image data and the orientation data to engrave the image onto the device; and
operate the applicator based on the image data and the orientation data to apply the ink to the image.

14. The system of claim 12, wherein the controller is configured to apply the ink to substantially only the engraved image on the device.

15. A device having a multi-color image formed thereon, the device comprising:
a housing having an image engraved thereon; and
ink of multiple colors on the image, a first portion of the image having a first color and a second portion of the image having a second color.

16. The device of claim 15, wherein the ink comprises a UV curing ink.

17. The device of claim 15, further comprising a base ink under the ink of multiple colors.

18. The device of claim 15, wherein the device is an electronic device.

19. The device of claim 15, wherein the device comprises a metal surface and wherein the image is engraved onto the metal surface.

20. A method of forming an image onto a device, the method comprising:
engraving an image onto an electronic device, the electronic device having a base material and a coating material above the base material, wherein engraving the image comprises removing the coating material to expose the base material for an image area; and
applying a coloring agent to the image area, the coloring agent configured to cause a chemical reaction with the base material to change the color of the image.

21. The method of claim 20, wherein the base material comprises a metal.

22. The method of claim 20, wherein the coloring agent comprises an acidic liquid.

23. The method of claim 20, wherein the chemical reaction forms a layer of an oxide of the base material in the image area.

24. A device having an image formed thereon, the device comprising:
a housing having a base material and a coating material above the base material;
an image engraved onto the housing, the image having an image area with the coating material removed to expose the base material; and
a layer of material in the image area, the material comprising an oxide of the base material, the oxide of the base material having a different color than the base material.

25. The device of claim 24, wherein the base material comprises a metal.
